(19) United States
(12) Patent Application Publication
(10) Pub. No.: US 2025/0062746 A1
(43) Pub. Date: Feb. 20, 2025

(54) TUNABLE SINGLE-INPUT DUAL-OUTPUT ACOUSTIC FILTER CIRCUIT

(71) Applicant: Qorvo US, Inc., Greensboro, NC (US)

(72) Inventor: Nadim Khlat, Cugnaux (FR)

(21) Appl. No.: 18/775,509

(22) Filed: Jul. 17, 2024

Related U.S. Application Data
(60) Provisional application No. 63/520,455, filed on Aug. 18, 2023.
(60) Provisional application No. 63/587,813, filed on Oct. 4, 2023.

(51) Int. Cl. H03H 9/54; H03H 9/205

(52) U.S. Cl. CPC H03H 9/54; H03H 9/205

(57) ABSTRACT

A tunable single-input dual-output (SIDO) acoustic filter circuit is provided. Specifically, the tunable SIDO acoustic filter circuit includes one input port and two output ports. The input port is configured to receive a signal in a band-pass frequency range or in a band-stop frequency range outside the band-pass frequency range. When the signal is modulated in the band-pass frequency range, the acoustic band-pass and band-stop filter can output the signal via a first one of the output ports. When the signal is modulated in the band-stop frequency range, the acoustic band-pass and band-stop filter can output the signal via a second one of the output ports. In an embodiment, the band-pass frequency range, and accordingly the band-stop frequency range, can be statically or dynamically tuned by a tuning voltage. As such, the tunable SIDO acoustic filter circuit can be flexibly tuned to support a variety of band-pass and band-stop frequencies.

### RELATED APPLICATIONS

This application claims the benefit of U.S. provisional patent application Ser. No. 63/520,455, filed on Aug. 18, 2023, and U.S. provisional patent application Ser. No. 63/587,813, filed on Oct. 4, 2023, the disclosures of which are hereby incorporated herein by reference in their entireties.

### FIELD OF THE DISCLOSURE

The technology of the disclosure relates generally to an acoustic filter that can be tuned to output a signal in two non-overlapping frequency ranges.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications.

Ferroelectric acoustic resonators, such as ferroelectric bulk acoustic resonators (FBARs), offer ultra-small size and can operate at frequencies up to tens of gigahertz. As such, ferroelectric resonators are widely used as miniaturized filters in many high-frequency devices, such as fifth generation (5G) and 5G new radio (5G-NR) communication and/or navigation devices. The operating frequency (a.k.a. series/parallel resonance frequency) of a ferroelectric acoustic resonator is typically determined by an inner structure (e.g., thickness and elastic properties) of the ferroelectric acoustic resonator. As such, it is desirable to electrically control the ferroelectric acoustic resonator to operate at a desired operating frequency without changing the inner structure of the ferroelectric acoustic resonator.

### SUMMARY

Aspects disclosed in the detailed description include a tunable single-input dual-output (SIDO) acoustic filter circuit. Specifically, the tunable SIDO acoustic filter circuit includes one input port and two output ports. The input port is configured to receive a signal, which can be modulated in a band-pass frequency range or a band-stop frequency range outside (a.k.a. non-overlapping with) the band-pass frequency range. When the signal is modulated in the band-pass frequency range, the acoustic band-pass and band-stop filter can output the signal via a first one of the output ports. When the signal is modulated in the band-stop frequency range, the acoustic band-pass and band-stop filter can output the signal via a second one of the output ports. In an embodiment, the band-pass frequency range, and accordingly the band-stop frequency range, can be statically or dynamically tuned by a tuning voltage. As a result, the tunable SIDO acoustic filter circuit can be flexibly tuned to support a variety of band-pass and band-stop frequencies.

In one aspect, an acoustic resonator structure is provided. The acoustic resonator structure includes a ferroelectric coupling layer. The ferroelectric coupling layer is configured to tune a band-pass frequency range in response to receiving a tuning voltage. The acoustic resonator structure also includes a pair of acoustic resonators. The pair of acoustic resonators are coupled to each other via the ferroelectric coupling layer. The pair of acoustic resonators is interconnected between an input port and an output port to block a signal between the input port and the output port inside the band-pass frequency range and pass the signal from the input port to the output port outside the band-pass frequency range.

In another aspect, a tunable SIDO acoustic filter circuit is provided. The tunable SIDO acoustic filter circuit includes an input circuit. The input circuit is configured to receive a signal and output the signal in a band-pass frequency range. The tunable SIDO acoustic filter circuit also includes an output circuit. The output circuit is configured to output the signal in a band-stop frequency range outside the band-pass frequency range. The tunable SIDO acoustic filter circuit also includes an in-phase path and a quadrature path. The in-phase path and the quadrature path are provided in parallel between the input circuit and the output circuit. Each of the in-phase path and the quadrature path is configured to block the signal in the band-pass frequency range to thereby cause the signal to be outputted from the input circuit. Each of the in-phase path and the quadrature path is also configured to pass the signal in the band-stop frequency range to thereby cause the signal to be outputted from the output circuit.

In another aspect, a wireless device is provided. The wireless device includes a tunable SIDO acoustic filter circuit. The tunable SIDO acoustic filter circuit includes an input circuit. The input circuit is configured to receive a signal and output the signal in a band-pass frequency range. The tunable SIDO acoustic filter circuit also includes an output circuit. The output circuit is configured to output the signal in a band-stop frequency range outside the band-pass frequency range. The tunable SIDO acoustic filter circuit also includes an in-phase path and a quadrature path. The in-phase path and the quadrature path are provided in parallel between the input circuit and the output circuit. Each of the in-phase path and the quadrature path is configured to block the signal in the band-pass frequency range to thereby cause the signal to be outputted from the input circuit. Each of the in-phase path and the quadrature path is also configured to pass the signal in the band-stop frequency range to thereby cause the signal to be outputted from the output circuit.

In another aspect, a method for operating a tunable SIDO acoustic filter circuit is provided. The method includes providing an in-phase path and a quadrature path in parallel between an input circuit and an output circuit. The method also includes configuring each of the in-phase path and the quadrature path to block a signal in a band-pass frequency range to thereby cause the signal to be outputted from the input circuit. The method also includes configuring each of in-phase path and the quadrature path to pass the signal in a band-stop frequency range outside the band-pass frequency range to thereby cause the signal to be outputted from the output circuit.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram illustrating an exemplary definition of a band-pass frequency range and a band-stop frequency range in context of the present disclosure;

FIGS. 2A and 2B are schematic diagrams of an exemplary acoustic resonator structure each configured according to embodiments of the present disclosure to block a signal in the band-pass frequency range in FIG. 1 and pass the signal in the band-stop frequency range in FIG. 1;

FIG. 3 is a schematic diagram of an exemplary tunable single-input dual-output (SIDO) acoustic filter circuit configured using the acoustic resonator structure in FIGS. 2A and/or 2B;

FIG. 4 is a graphic diagram of an exemplary tunable SIDO acoustic filter circuit adapted from the tunable SIDO acoustic filter circuit of FIG. 3;

FIG. 5 is a schematic diagram of an exemplary communication device wherein the tunable SIDO acoustic filter circuit of FIG. 3 and the Tunable SIDO acoustic filter circuit of FIG. 4 can be provided; and

FIG. 6 is a flowchart of an exemplary process for operating the tunable SIDO acoustic filter circuits of FIGS. 3 and 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a tunable single-input dual-output (SIDO) acoustic filter circuit. Specifically, the tunable SIDO acoustic filter circuit includes one input port and two output ports. The input port is configured to receive a signal, which can be modulated in a band-pass frequency range or a band-stop frequency range outside (a.k.a. non-overlapping with) the band-pass frequency range. When the signal is modulated in the band-pass frequency range, the acoustic band-pass and band-stop filter can output the signal via a first one of the output ports. When the signal is modulated in the band-stop frequency range, the acoustic band-pass and band-stop filter can output the signal via a second one of the output ports. In an embodiment, the band-pass frequency range, and accordingly the band-stop frequency range, can be statically or dynamically tuned by a tuning voltage. As a result, the tunable SIDO acoustic filter circuit can be flexibly tuned to support a variety of band-pass and band-stop frequencies.

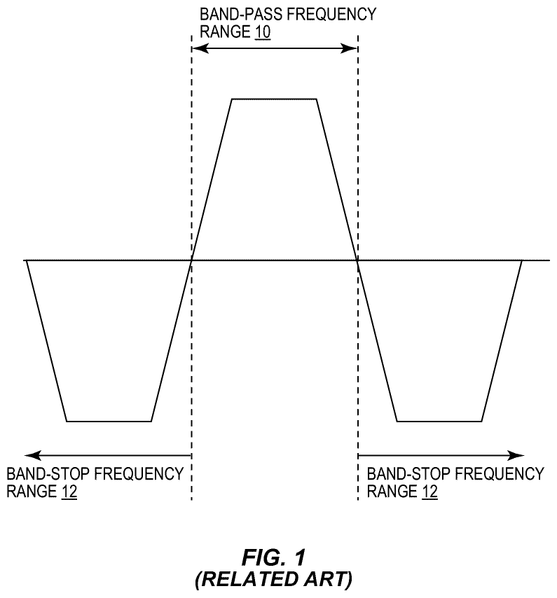

FIG. 1 is a schematic diagram illustrating an exemplary definition of a band-pass frequency range 10 and a band-stop frequency range 12 in context of the present disclosure. As illustrated in FIG. 1, the band-stop frequency range 12 is located outside the band-pass frequency range 10. In other words, the band-stop frequency range 12 does not overlap with the band-pass frequency range 10.

In context of the present disclosure, the band-pass frequency range 10 and the band-stop frequency range 12 are contrary to conventional definitions of a band-pass frequency region and a band-stop frequency region. Herein, the band-pass frequency range 10 defines a frequency range wherein a signal will be blocked and the band-stop frequency range 12 defines a frequency range wherein a signal will not be blocked (a.k.a. passed). As discussed below, the band-pass frequency range 10 and, accordingly the band-stop frequency range 12, can be tuned (a.k.a. changed) either statically or dynamically.

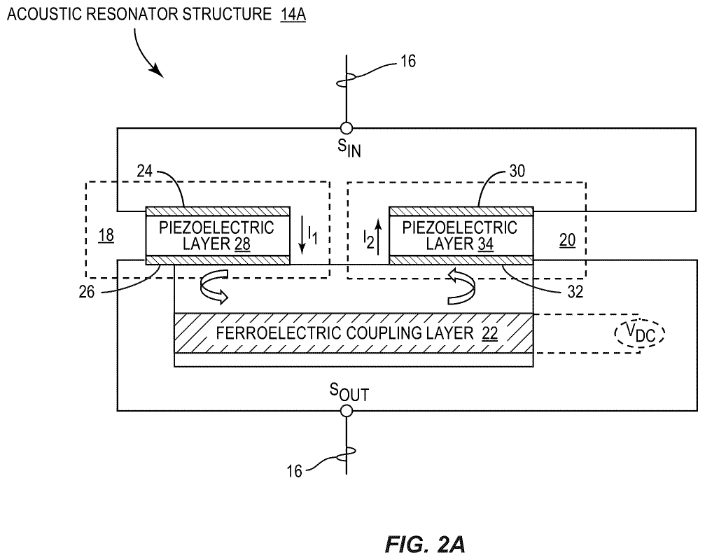

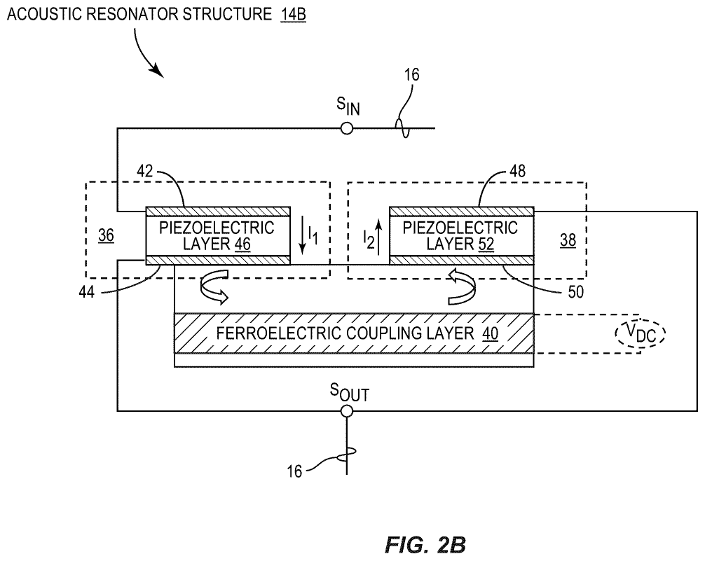

FIG. 2A is a schematic diagram of an exemplary acoustic resonator structure 14A configured according to one embodiment of the present disclosure to block a signal 16 between an input port SIN and an output port Sour in the band-pass frequency range 10 in FIG. 1 and pass the signal 16 from the input port SIN to the output port Sour in the band-stop frequency range 12 in FIG. 1. Common elements between FIGS. 1 and 2A are referenced therein with common element numbers and will not be re-described herein.

The acoustic resonator structure 14A includes a first acoustic resonator 18, a second acoustic resonator 20, and a ferroelectric coupling layer 22. The first acoustic resonator 18 includes a first electrode 24, a second electrode 26, and a first piezoelectric layer 28 provided between the first electrode 24 and the second electrode 26. The second acoustic resonator 20 includes a third electrode 30, a fourth electrode 32, and a second piezoelectric layer 34 provided between the third electrode 30 and the fourth electrode 32.

The first acoustic resonator 18 and the second acoustic resonator 20 are acoustically coupled via the ferroelectric coupling layer 22. The ferroelectric coupling layer 22 can be tuned, either statically or dynamically, by a tuning voltage V_{DC} to cause the first acoustic resonator 18 and the second acoustic resonator 20 to each resonate in the band-pass frequency range 10.

To cause the first acoustic resonator 18 and the second acoustic resonator 20 to each block the signal 16 between the input port SIN and the output port Sour in the band-pass frequency range 10, the acoustic resonator structure 14A is configured herein to cause a first current I₁ in the first acoustic resonator 18 to have an opposite polarity from a second current I₂ in the second acoustic resonator 20. As a result, the first current I₁ will offset the second current I₂ in the band-pass frequency range 10 to thereby prevent the signal 16 from flowing from the input port S_{IN} to the output port Sour. In a way, a nullification of the first current I₁ and the second current I₂ is equivalent to creating a high impedance between the input port S_{IN} to the output port Sour to thereby block the signal 16.

Outside the band-pass frequency range 10, the first current I₁ will not completely offset the second current I₂. In other words, a lower impedance will be created between the input port S_{IN} to the output port Sour to thereby pass the signal 16 from the input port S_{IN} to the output port S_{OUT}.

In an embodiment, the first electrode 24 of the first acoustic resonator 18 and the third electrode 30 of the second acoustic resonator 20 are both connected to the input port S_{IN}, and the second electrode 26 of the first acoustic resonator 18 and the fourth electrode 32 of the second acoustic resonator 20 are both connected to the output port Sour. To nullify the first current I₁ and the second current I₂, the first piezoelectric layer 28 and the second piezoelectric layer 34 are made with an inverted polarity material (e.g., aluminum nitride). For example, the first piezoelectric layer 28 can be made with a c-type piezoelectric material and the second piezoelectric layer 34 can be made with an f-type piezoelectric material.

FIG. 2B is a schematic diagram of an exemplary acoustic resonator structure 14B configured according to another embodiment of the present disclosure to block the signal 16 between the input port S_{IN} and the output port S_{OUT} in the band-pass frequency range 10 in FIG. 1 and pass the signal 16 from the input port S_{IN} to the output port Sour in the band-stop frequency range 12 in FIG. 1. Common elements between FIGS. 2A and 2B are referenced therein with common element numbers and will not be re-described herein.

The acoustic resonator structure 14B includes a first acoustic resonator 36, a second acoustic resonator 38, and a ferroelectric coupling layer 40. The first acoustic resonator 36 includes a first electrode 42, a second electrode 44, and a first piezoelectric layer 46 provided between the first electrode 42 and the second electrode 44. The second acoustic resonator 38 includes a third electrode 48, a fourth electrode 50, and a second piezoelectric layer 52 provided between the third electrode 48 and the fourth electrode 50.

The first acoustic resonator 36 and the second acoustic resonator 38 are acoustically coupled via the ferroelectric coupling layer 40. The ferroelectric coupling layer 40 can be tuned, either statically or dynamically, by a tuning voltage V_{DC} to cause the first acoustic resonator 36 and the second acoustic resonator 38 to each resonate in the band-pass frequency range 10.

To cause the first acoustic resonator 36 and the second acoustic resonator 38 to each block the signal 16 between the input port S_{IN} and the output port Sour in the band-pass frequency range 10, the acoustic resonator structure 14B is also configured herein to cause the first current I₁ in the first acoustic resonator 36 to have an opposite polarity from the second current I₂ in the second acoustic resonator 38. As a result, the first current I₁ will offset the second current I₂ in the band-pass frequency range 10 to thereby prevent the signal 16 from flowing from the input port S_{IN} to the output port Sour. In a way, a nullification of the first current I₁ and the second current I₂ is equivalent to creating a high impedance between the input port S_{IN} to the output port Sour to thereby block the signal 16.

Outside the band-pass frequency range 10, the first current I₁ will not completely offset the second current I₂. In other words, a lower impedance will be created between the input port S_{IN} to the output port Sour to thereby pass the signal 16 from the input port S_{IN} to the output port S_{OUT}.

In an embodiment, the first electrode 42 of the first acoustic resonator 36 and the fourth electrode 50 of the second acoustic resonator 38 are both connected to the input port S_{IN}, and the second electrode 44 of the first acoustic resonator 36 and the third electrode 48 of the second acoustic resonator 38 are both connected to the output port S_{OUT}. By interconnecting the first acoustic resonator 36 and the second acoustic resonator 38 between the input port S_{IN} to the output port Sour, as illustrated herein, the first current I₁ and the second current I₂ will be nullified to thereby block the signal 16 between the input port S_{IN} and the output port S_{OUT}.

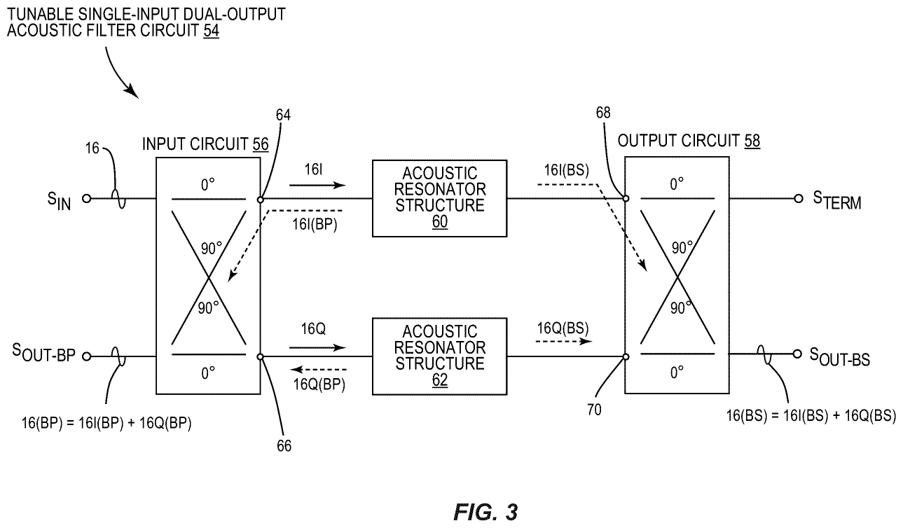

The acoustic resonator structure 14A of FIG. 2A and/or the acoustic resonator structure 14B of FIG. 2B can be provided in a SIDO acoustic filter circuit to selectively output the signal 16 in the band-pass frequency range 10 or in the band-stop frequency range 12. FIG. 3 is a schematic diagram of an exemplary tunable SIDO acoustic filter circuit 54 configured using the acoustic resonator structure 14A in FIG. 2A and/or the acoustic resonator structure 14B in FIG. 2B. Common elements between FIGS. 2A, 2B, and 3 are referenced therein with common element numbers and will not be re-described herein.

Herein, the tunable SIDO acoustic filter circuit 54 includes a single input port S_{IN} and two output ports, namely a band-pass output port S_{OUT-BP} and a band-stop output port S_{OUT-BS}. The tunable SIDO acoustic filter circuit 54 is configured to receive the signal 16 via the input port S_{IN}. When the signal 16 is modulated in the band-pass frequency range 10, the tunable SIDO acoustic filter circuit 54 outputs the signal 16 via the band-pass output port S_{OUT-BP}. When the signal 16 is modulated in the band-stop frequency range 12, the tunable SIDO acoustic filter circuit 54 outputs the signal 16 via the band-stop output port S_{OUT-BS}.

In an embodiment, the tunable SIDO acoustic filter circuit 54 includes an input circuit 56 and an output circuit 58. Herein, the input circuit 56 is coupled to the input port S_{IN} and the band-pass output port S_{OUT-BP}, and the output circuit 58 is coupled to the band-stop output port S_{OUT-BS} and a terminating port S_{TERM}. The tunable SIDO acoustic filter circuit 54 also includes a pair of acoustic resonator structures 60, 62 provided in parallel between the input circuit 56 and the output circuit 58. Herein, each of the acoustic resonator structures 60, 62 can be the acoustic resonator structure 14A or the acoustic resonator structure 14B. Accordingly, each of the acoustic resonator structures 60, 62 can be tuned to block the signal 16 between the input circuit 56 and the output circuit 58 in the band-pass frequency range 10 and pass the signal 16 from the input circuit 56 to the output circuit 58 in the band-stop frequency range 12.

The input circuit 56 is configured to receive the signal 16 via the input port S_{IN} and split the signal 16 into an in-phase signal 16I and a quadrature signal 16Q, each having an identical content and in an identical frequency range (e.g., the band-pass frequency range 10 or the band-stop frequency range 12) as the signal 16, but with less power (e.g., one-half) compared to the signal 16. The input circuit 56 then outputs the in-phase signal 16I and the quadrature signal 16Q via an in-phase output 64 and a quadrature output 66, respectively.

In an embodiment, the acoustic resonator structure 60 is coupled to the in-phase output 64 to receive the in-phase signal 16I. As such, the acoustic resonator structure 60 is also referred to as an in-phase path 60. The acoustic resonator structure 62, on the other hand, is coupled to the quadrature output 66 to receive the quadrature signal 16Q. Accordingly, the acoustic resonator structure 62 is also referred to as a quadrature path 62.

As previously discussed in FIGS. 2A and 2B, the in-phase path 60 and the quadrature path 62 can each be configured to block a respective one of the in-phase signal 16I and the quadrature signal 16Q, and to pass the respective one of the in-phase signal 16I and the quadrature signal 16Q. In this regard, when the in-phase signal 16I and the quadrature signal 16Q fall within the band-pass frequency range 10, the in-phase path 60 will reflect the in-phase signal 16I back toward the in-phase output 64 and the quadrature path 62 will reflect the quadrature signal 16Q back toward the quadrature output 66. The input circuit 56, in turn, will make a ninety-degree) (90° phase shift on the reflected in-phase signal 16| (BP) and then combine with the reflected quadrature signal 16Q (BP) to thereby output the signal 16 via the band-pass output port S_{OUT-BP}.

In contrast, when the in-phase signal 16I and the quadrature signal 16Q fall within the band-stop frequency range 12, the in-phase path 60 will pass the in-phase signal 16I to an in-phase input 68 of the output circuit 58 and the quadrature path 62 will pass the quadrature signal 16Q to a quadrature input 70 of the output circuit 58. The output circuit 58, in turn, will make a 90° phase shift on the in-phase signal 16I (BS) and then combine with the received quadrature signal 16Q (BS) to thereby output the signal 16 via the band-stop output port S_{OUT-BS}.

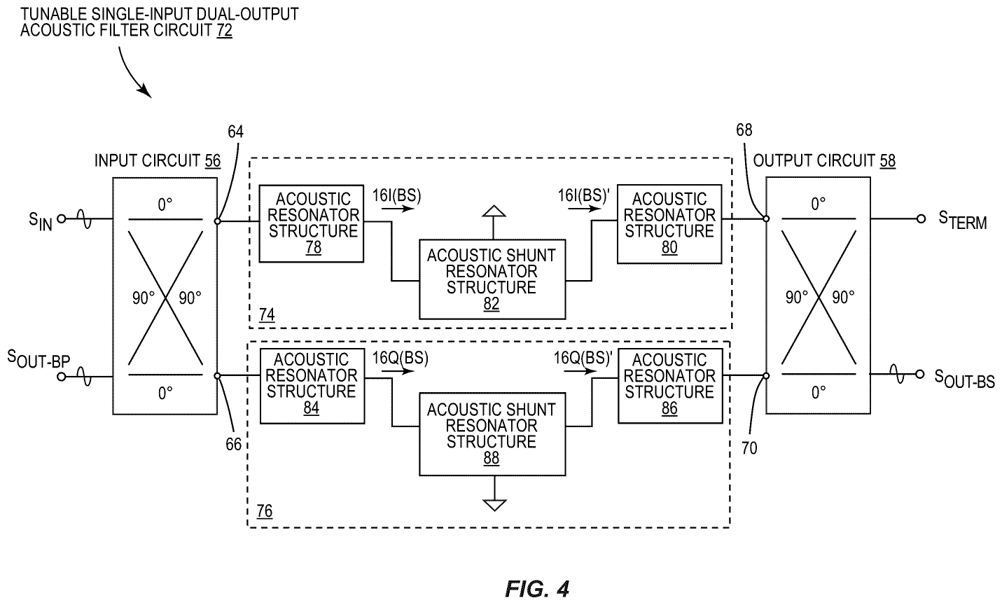

The topology of the tunable SIDO acoustic filter circuit 54 may be extended to form a SIDO acoustic filter network. In this regard, FIG. 4 is a graphic diagram of an exemplary SIDO acoustic filter network 72 adapted from the tunable SIDO acoustic filter circuit 54 of FIG. 3. Common elements between FIGS. 3 and 4 are referenced therein with common element numbers and will not be re-described herein.

Herein, the SIDO acoustic filter network 72 includes an in-phase path 74 and a quadrature path 76. In an embodiment, the in-phase path 74 includes a pair of in-phase acoustic resonator structures 78, 80 and an in-phase acoustic shunt resonator structure 82 coupled between the in-phase acoustic resonator structures 78, 80. Each of the in-phase acoustic resonator structures 78, 80 and the in-phase acoustic shunt resonator structure 82 can be configured to function as the acoustic resonator structure 14A or the acoustic resonator structure 14B.

The quadrature path 76 includes a pair of quadrature acoustic resonator structures 84, 86 and a quadrature acoustic shunt resonator structure 88 coupled between the quadrature acoustic resonator structures 84, 86. Each of the quadrature acoustic resonator structures 84, 86 and the quadrature acoustic shunt resonator structure 88 can be configured to function as the acoustic resonator structure 14A or the acoustic resonator structure 14B.

In an embodiment, the SIDO acoustic filter network 72 may provide a finer filtering in the band-stop frequency range 12. As an example, the in-phase shunt acoustic resonator structure 82 can shunt a portion of the in-phase signal 16| (BS) outputted by the in-phase acoustic resonator structure 78 and then provide a remainder of the in-phase signal 16I (BS)′ to the in-phase acoustic resonator structure 80. Likewise, the quadrature shunt acoustic resonator structure 88 can shunt a portion of the quadrature signal 16Q (BS) outputted by the quadrature acoustic resonator structure 84 and then provide a remainder of the quadrature signal 16Q (BS)′ to the quadrature acoustic resonator structure 86.

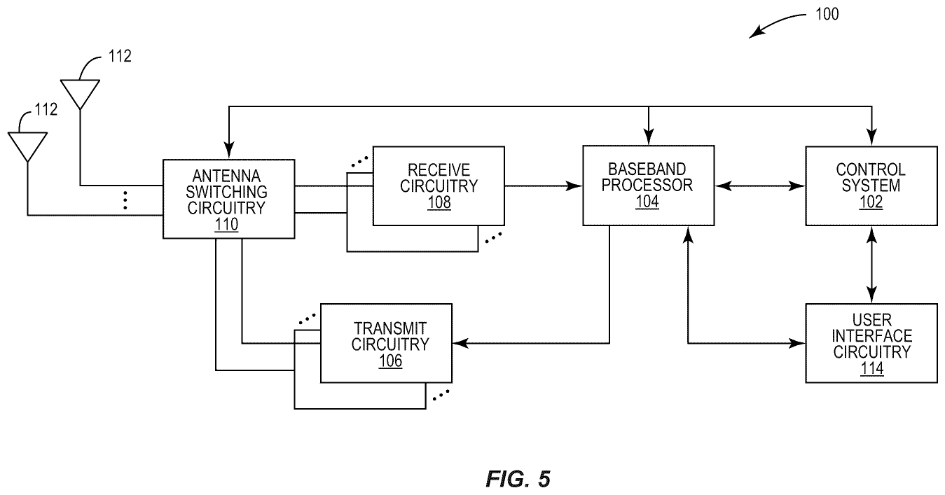

The tunable SIDO acoustic filter circuit 54 of FIG. 3 and the Tunable SIDO acoustic filter circuit 72 of FIG. 4 can be provided in a communication device to support the embodiments described above. In this regard, FIG. 5 is a schematic diagram of an exemplary communication device 100 wherein the tunable SIDO acoustic filter circuit 54 of FIG. 3 and the Tunable SIDO acoustic filter circuit 72 of FIG. 4 can be provided.

Herein, the communication device 100 can be any type of communication devices, such as mobile terminals, smart watches, tablets, computers, navigation devices, access points, and like wireless communication devices that support wireless communications, such as cellular, wireless local area network (WLAN), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the tunable SIDO acoustic filter circuit 54 of FIG. 3 and the Tunable SIDO acoustic filter circuit 72 of FIG. 4 can be provided in the transmit circuitry 106, the receive circuitry 108, and/or the antenna switching circuitry 110. Understandably, tunable SIDO acoustic filter circuit 54 and the Tunable SIDO acoustic filter circuit 72 may also be provided anywhere else in the communication device 100.

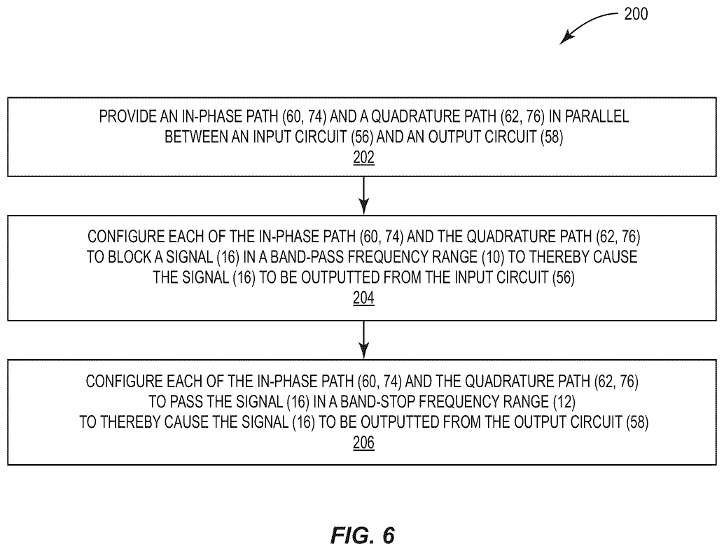

In an embodiment, the tunable SIDO acoustic filter circuit 54 of FIG. 3 and the SIDO acoustic filter network 72 of FIG. 4 can be operated in accordance with a process. In this regard, FIG. 6 is a flowchart of an exemplary process 200 for operating tunable SIDO acoustic filter circuit 54 of FIG. 3 and the SIDO acoustic filter network 72 of FIG. 4.

Herein, the process 200 includes providing the in-phase path 60, 74 and the quadrature path 62, 76 in parallel between the input circuit 56 and the output circuit 58 (step 202). The process 200 also includes configuring each of the in-phase path 60, 74 and the quadrature path 62, 76 to block the signal 16 in the band-pass frequency range 10 to thereby cause the signal 16 to be outputted from the input circuit 56 (step 204). The process 200 also includes configuring each of the in-phase path 60, 74 and the quadrature path 62, 76 to pass the signal 16 in the band-stop frequency range 12 to thereby cause the signal 16 to be outputted from the output circuit 58 (step 206).

Those skilled in the art will recognize improvements and modifications to the embodiments of the present disclosure. All such improvements and modifications are considered within the scope of the concepts disclosed herein and the claims that follow.

What is claimed is:

1. An acoustic resonator structure comprising:
a ferroelectric coupling layer configured to tune a band-pass frequency range in response to receiving a tuning voltage; and
a pair of acoustic resonators coupled to each other via the ferroelectric coupling layer and interconnected between an input port and an output port to:
block a signal between the input port and the output port inside the band-pass frequency range; and
pass the signal from the input port to the output port outside the band-pass frequency range.

2. The acoustic resonator structure of claim 1, wherein the pair of acoustic resonators comprise:
a first acoustic resonator comprising a first electrode, a second electrode, and a first piezoelectric layer provided between the first electrode and the second electrode; and
a second acoustic resonator comprising a third electrode, a fourth electrode, and a second piezoelectric layer provided between the third electrode and the fourth electrode.

3. The acoustic resonator structure of claim 2, wherein:
the first electrode and the third electrode are connected to the input port;
the second electrode and the fourth electrode are connected to the output port; and
the first piezoelectric layer and the second piezoelectric layer are made with materials having inverted polarities.

4. The acoustic resonator structure of claim 2, wherein:
the first electrode and the fourth electrode are connected to the input port;
the second electrode and the third electrode are connected to the output port; and
the first piezoelectric layer and the second piezoelectric layer are made with materials having non-inverted polarities.

5. A tunable single-input dual-output (SIDO) acoustic filter circuit comprising:
an input circuit configured to receive a signal and output the signal in a band-pass frequency range;
an output circuit configured to output the signal in a band-stop frequency range outside the band-pass frequency range; and
an in-phase path and a quadrature path provided in parallel between the input circuit and the output circuit and each configured to:
block the signal in the band-pass frequency range to thereby cause the signal to be outputted from the input circuit; and
pass the signal in the band-stop frequency range to thereby cause the signal to be outputted from the output circuit.

6. The tunable SIDO acoustic filter circuit of claim 5, wherein:
the in-phase path comprises an in-phase acoustic resonator structure coupled between an in-phase output of the input circuit and an in-phase input of the output circuit, the in-phase acoustic resonator structure is configured to:
receive an in-phase signal via the in-phase output of the input circuit;
reflect the in-phase signal back to the in-phase output of the input circuit when the in-phase signal is within the band-pass frequency range; and
pass the in-phase signal to the in-phase input of the output circuit when the in-phase signal is within the band-stop frequency range; and
the quadrature path comprises a quadrature acoustic resonator structure coupled between a quadrature output of the input circuit and a quadrature input of the output circuit, the quadrature acoustic resonator structure is configured to:
receive a quadrature signal via the quadrature output of the input circuit;
reflect the quadrature signal back to the quadrature output of the input circuit when the quadrature signal is within the band-pass frequency range; and
pass the quadrature signal to the quadrature input of the output circuit when the quadrature signal is within the band-stop frequency range.

7. The tunable SIDO acoustic filter circuit of claim 6, wherein the input circuit is configured to:
receive the signal via an input port;
split the signal into the in-phase signal and the quadrature signal;
provide the in-phase signal and the quadrature signal to the in-phase output and the quadrature output, respectively;
receive the in-phase signal and the quadrature signal in the band-pass frequency range via the in-phase output and the quadrature output, respectively;
combine the in-phase signal and the quadrature signal into the signal in the band-pass frequency range; and
output the signal via a band-pass output port.

8. The tunable SIDO acoustic filter circuit of claim 6, wherein the output circuit is configured to:
receive the in-phase signal and the quadrature signal in the band-stop frequency range via the in-phase input and the quadrature input, respectively;
combine the in-phase signal and the quadrature signal into the signal in the band-stop frequency range; and
output the signal via a band-stop output port.

9. The tunable SIDO acoustic filter circuit of claim 6, wherein each of the in-phase acoustic resonator structure and the quadrature acoustic resonator structure comprises:
a ferroelectric coupling layer configured to tune the band-pass frequency range in response to receiving a tuning voltage; and
a pair of acoustic resonators coupled to each other via the ferroelectric coupling layer and interconnected to:
block the signal inside the band-pass frequency range; and
pass the signal outside the band-pass frequency range.

10. The tunable SIDO acoustic filter circuit of claim 9, wherein the pair of acoustic resonators comprise:
a first acoustic resonator comprising a first electrode, a second electrode, and a first piezoelectric layer provided between the first electrode and the second electrode; and
a second acoustic resonator comprising a third electrode, a fourth electrode, and a second piezoelectric layer provided between the third electrode and the fourth electrode.

11. The tunable SIDO acoustic filter circuit of claim 10, wherein:
the first electrode and the third electrode are connected to a respective one of the in-phase output and the quadrature output;
the second electrode and the fourth electrode are connected to a respective one of the in-phase input and the quadrature input; and
the first piezoelectric layer and the second piezoelectric layer are made with materials having inverted polarities.

12. The tunable SIDO acoustic filter circuit of claim 10, wherein:
the first electrode and the fourth electrode are connected to a respective one of the in-phase output and the quadrature output;
the second electrode and the third electrode are connected to a respective one of the in-phase input and the quadrature input; and
the first piezoelectric layer and the second piezoelectric layer are made with materials having non-inverted polarities.

13. The tunable SIDO acoustic filter circuit of claim 5, wherein:
the in-phase path comprises:
a pair of in-phase acoustic resonator structures coupled in series between an in-phase output of the input circuit and an in-phase input of the output circuit; and
an in-phase acoustic shunt resonator structure coupled between the pair of in-phase acoustic resonator structures; and
the quadrature path comprises:
a pair of quadrature acoustic resonator structures coupled in series between a quadrature output of the input circuit and a quadrature input of the output circuit; and
a quadrature acoustic shunt resonator structure coupled between the pair of quadrature acoustic resonator structures.

14. A wireless device comprising a tunable single-input dual-output (SIDO) acoustic filter circuit, the tunable SIDO acoustic filter circuit comprising:
an input circuit configured to receive a signal and output the signal in a band-pass frequency range;
an output circuit configured to output the signal in a band-stop frequency range outside the band-pass frequency range; and
an in-phase path and a quadrature path provided in parallel between the input circuit and the output circuit and each configured to:
block the signal in the band-pass frequency range to thereby cause the signal to be outputted from the input circuit; and
pass the signal in the band-stop frequency range to thereby cause the signal to be outputted from the output circuit.

15. The wireless device of claim 14, wherein:
the in-phase path comprises an in-phase acoustic resonator structure coupled between an in-phase output of the input circuit and an in-phase input of the output circuit, the in-phase acoustic resonator structure is configured to:
receive an in-phase signal via the in-phase output of the input circuit;
reflect the in-phase signal back to the in-phase output of the input circuit when the in-phase signal is within the band-pass frequency range; and
pass the in-phase signal to the in-phase input of the output circuit when the in-phase signal is within the band-stop frequency range; and
the quadrature path comprises a quadrature acoustic resonator structure coupled between a quadrature output of the input circuit and a quadrature input of the output circuit, the quadrature acoustic resonator structure is configured to:
receive a quadrature signal via the quadrature output of the input circuit;
reflect the quadrature signal back to the quadrature output of the input circuit when the quadrature signal is within the band-pass frequency range; and
pass the quadrature signal to the quadrature input of the output circuit when the quadrature signal is within the band-stop frequency range.

16. The wireless device of claim 15, wherein the input circuit is configured to:
receive the signal via an input port;
split the signal into the in-phase signal and the quadrature signal;
provide the in-phase signal and the quadrature signal to the in-phase output and the quadrature output, respectively;
receive the in-phase signal and the quadrature signal in the band-pass frequency range via the in-phase output and the quadrature output, respectively;
combine the in-phase signal and the quadrature signal into the signal in the band-pass frequency range; and
output the signal via a band-pass output port.

17. The wireless device of claim 15, wherein the output circuit is configured to:
receive the in-phase signal and the quadrature signal in the band-stop frequency range via the in-phase input and the quadrature input, respectively;
combine the in-phase signal and the quadrature signal into the signal in the band-stop frequency range; and
output the signal via a band-stop output port.

18. The wireless device of claim 15, wherein each of the in-phase acoustic resonator structure and the quadrature acoustic resonator structure comprises:
a ferroelectric coupling layer configured to tune the band-pass frequency range in response to receiving a tuning voltage; and
a pair of acoustic resonators coupled to each other via the ferroelectric coupling layer and interconnected to:
block the signal inside the band-pass frequency range; and
pass the signal outside the band-pass frequency range.

19. The wireless device of claim 14, wherein:
the in-phase path comprises:
a pair of in-phase acoustic resonator structures coupled in series between an in-phase output of the input circuit and an in-phase input of the output circuit; and
an in-phase acoustic shunt resonator structure coupled between the pair of in-phase acoustic resonator structures; and
the quadrature path comprises:
a pair of quadrature acoustic resonator structures coupled in series between a quadrature output of the input circuit and a quadrature input of the output circuit; and
a quadrature acoustic shunt resonator structure coupled between the pair of quadrature acoustic resonator structures.

20. A method for operating a tunable single-input dual-output (SIDO) acoustic filter circuit comprising:
providing an in-phase path and a quadrature path in parallel between an input circuit and an output circuit;
configuring each of the in-phase path and the quadrature path to block a signal in a band-pass frequency range to thereby cause the signal to be outputted from the input circuit; and
configuring each of in-phase path and the quadrature path to pass the signal in a band-stop frequency range outside the band-pass frequency range to thereby cause the signal to be outputted from the output circuit.
